(19) United States
(12) Patent Application Publication
(10) Pub. No.: US 2019/0386246 A1
(43) Pub. Date: Dec. 19, 2019

(54) DISPLAY DEVICE AND METHOD FOR MANUFACTURING THE SAME

(71) Applicant: INT TECH (HK) CO., LIMITED, Central (HK)

(72) Inventors: CHUNKANG KU, HSINCHU COUNTY (TW); YUCHI LU, YUNLIN COUNTY (TW); YIHSIN LAN, TAIPEI (TW)

(21) Appl. No.: 16/441,950

(22) Filed: Jun. 14, 2019

Related U.S. Application Data
(60) Provisional application No. 62/684,778, filed on Jun. 14, 2018.

(51) Int. Cl. H01L 51/52; C09D 183/08; C09D 163/00; C09D 133/08

(52) U.S. Cl. CPC H01L 51/5253; C09D 183/08; H01L 2251/30; C09D 133/08; C09D 163/00

(57) ABSTRACT

A display device includes an organic light emitting element and a cover layer. The organic light emitting element includes a thin-film encapsulation layer comprising an aluminum-containing material. The cover layer is disposed on the thin-film encapsulation layer, and the cover layer includes a silicon containing unit, an aluminum containing unit, and a bridging unit, and the aluminum-containing unit of the covering layer is covalently bonded to the thin-film encapsulating layer. A method of manufacturing a display device includes providing a dual-curable sol-gel composition comprising a silicon-containing monomer, an aluminum-containing monomer, a solvent, and a polymerization initiator, applying the composition to a thin-film encapsulation layer of an organic light-emitting device; and curing the composition with a UV radiation and at a curing temperature to form a cover layer on the thin-film encapsulation layer, wherein the curing temperature is a temperature that does not damage the organic light-emitting element.

### PRIORITY CLAIM AND CROSS REFERENCE

This application claims priority to U.S. patent provisional application No. 62/684,778, filed on Jun. 14, 2018, which is incorporated by reference in its entirety.

### FIELD OF INVENTION

The present disclosure relates generally to a display device and a method for manufacturing the same; particularly to a display device with a cover layer and a method for manufacturing the same.

### BACKGROUND

Display devices (such as display devices comprising organic light-emitting diodes (OLED)) have been integrated in various electronic devices, such as smartphones, for displaying.

As electronic devices evolve into various forms, display devices change accordingly; for example, display devices have to be flexible, durable, etc. Moreover, consumers demand thin display devices. In addition to integrated various functional components into the display device, more attention should be paid to the thickness of the display device.

### BRIEF SUMMARY OF THE INVENTION

Embodiments of the present disclosure provide a display device, wherein the display device includes an organic light-emitting element and a cover layer. The organic light-emitting element includes a circuit layer and a pixel layer formed on the circuit layer, and a thin-film encapsulation layer disposed on the pixel layer, wherein the thin-film encapsulation layer comprises an aluminum-containing material. The cover layer is disposed on the thin-film encapsulation layer of the organic light-emitting element, and the cover layer comprises a silicon-containing unit, an aluminum-containing unit, and a bridging unit connecting the silicon-containing unit and the aluminum-containing unit. The aluminum-containing unit of the cover layer is covalently bonded to the thin-film encapsulation layer.

Embodiments of the present disclosure further provide a method for manufacturing a display device. The manufacturing method includes, providing a dual-curable sol-gel composition, wherein the dual-curable sol-gel composition comprises a silicon-containing monomer, an aluminum-containing monomer, a solvent, and a polymerization initiator; applying the dual-curable sol-gel composition onto a surface of a thin-film encapsulation layer of an organic light-emitting element, wherein the thin-film encapsulation layer comprises an aluminum-containing material; and curing the dual-curable sol-gel composition with a UV radiation and at a curing temperature, thereby forming a cover layer on the surface of the thin-film encapsulation layer, wherein the curing temperature is a temperature that does not damage the organic light-emitting element.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of a display device according to one embodiment of the present invention;

FIG. 2 is cross-sectional view of the display device in FIG. 1 taken along the line A-A′, which illustrates the method for manufacturing the display device according to the present invention;

FIG. 3 is an IR spectrum illustrating the analysis result according to one embodiment of the present invention; and

FIG. 4 and FIG. 5 are cross-sectional views the display device in FIG. 1 taken along the line A-A′, which illustrates the method for manufacturing the display device according to the present invention.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide a display device having a cover layer and a method for manufacturing the same. The display device comprises the cover layer, which is configured to protect the organic light-emitting element. In some embodiments, the display device is flexible or bendable, wherein when the display device is bended or folded, the cover layer can be bended without breaking. The cover layer further exhibits good hardness, light transmittance, etc. The cover layer can be integrated onto and directly formed on the display surface of the display device without damaging the display device. Compared with the covering film attached to the display surface of the display device, the present integrally-formed cover layer eliminates the use of the extra adhesive film, thereby reducing the manufacturing cost and minimizing the overall thickness of the display device.

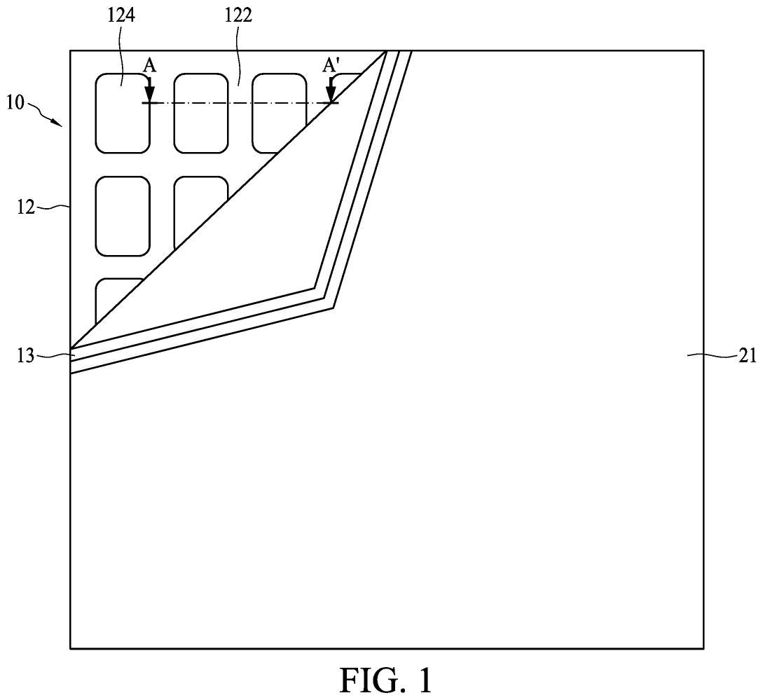

FIG. 1 is a top view illustrating a display device that comprises an organic light-emitting element 10 and a cover layer 21. The organic light-emitting element 10 comprises a circuit layer (not shown in the drawing), a pixel layer 12 formed on the circuit layer, and a thin-film encapsulation (TFE) layer 13 disposed on the pixel layer 12. In some embodiments, the pixel layer 12 includes a pixel defining layer 122, configured to provide a recess array for accommodating the array of the light-emitting material layer 124. The thin-film encapsulation layer 13 includes an aluminum-containing material, configured to prevent the moisture and impurity from entering into the pixel layer 12. The cover layer 21 includes a silicon-containing unit, an aluminum-containing unit, and a bridging unit connecting the silicon-containing unit and the aluminum-containing unit, wherein the aluminum-containing unit of the cover layer 21 is covalently bonded to the thin-film encapsulation layer 13.

In some embodiments, the cover layer 21 is a flexible hard coating layer. The cover layer 21 is flexible so that no fine cracks will form after multiple times of bending. Furthermore, the cover layer exhibits sufficient hardness so that is has a good wearability capable of withstanding long-term use, such as repetitive contact with the dust, cleaning apparatus, stylus on a daily basis. In some embodiments, when the display device is flexible or bendable, the cover layer 21 has a hardness of no less than the pencil hardness of 3H. In some embodiments, when the display device comprises a hard substrate and the cover layer 21, the cover layer 21 has a hardness of no less than the pencil hardness of 7H.

In some embodiments, the cover layer 21 has a light transmittance of no less than 85%, no less than 90%, or no less than 95%.

The cover layer 21 may be formed from, for example, a cross-linkable and polymerizable material. In some embodiments, an integrally-made cover layer 21 is formed by coating a dual-curable sol-gel composition on the thin-film encapsulation layer 13, wherein the curing step for the dual-curable sol-gel composition does not damage the organic light-emitting device 10. In some embodiments, a good compatibility between the cover layer 21 and the thin-film encapsulation layer 13 can be achieved by adjusting the components of the dual-curable sol-gel composition, thereby forming a tight connection therebetween, such as a covalent bond linkage.

In some embodiments, the cover layer 21 includes, but is not limited to, the repetitive structure of the following formula (I):

—X—Y—X—B— (I)

wherein, X represents the silicon-containing unit, Y represents the aluminum-containing unit, and B represents the bridging unit.

In some embodiments, the cover layer 21 includes a network structure, wherein the network structure includes silicon, aluminum, and oxygen. In some embodiments, the cover layer 21 includes, but is not limited to, the repetitive structure of the following formula (II):

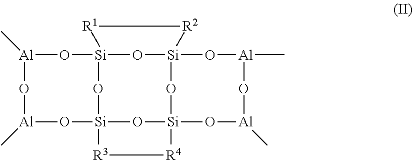

wherein, R¹, R², R³ and R⁴ is independently represented

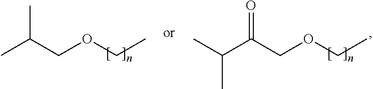

n is an integer between 3-20. In some embodiments, n is an integer between 3-8. In some embodiments, the carbon chain of R¹, R², R³ and R⁴ is bonded with silicon.

Take the repetitive structure of formula (II) as an example, the silicon-oxygen linkage and aluminum-oxygen linkage provide a desirable hardness for the cover layer 21, and the carbon chains of R¹, R², R³ and R⁴ provide a desirable flexibility for the cover layer 21.

In some embodiments, the cover layer 21 includes, but is not limited to, the repetitive structure of the following formula (III):

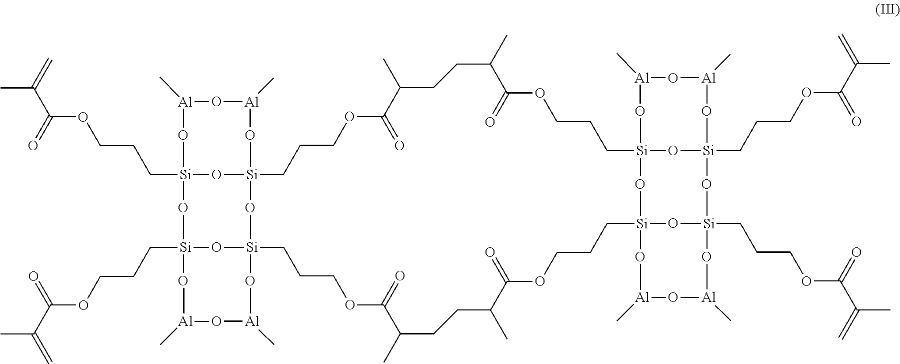

In some embodiments, the weight ratio between silicon and aluminum in the dual-curable sol-gel composition is 1:1 to 1:5.

In some embodiments, the aluminum-containing material of the thin-film encapsulation layer 13 includes, but is not limited to, aluminum oxide. In some embodiments, the aluminum-containing unit of the cover layer 21 is bonded with the aluminum of the aluminum-containing material of the thin-film encapsulation layer. In some embodiments, the cover layer 21 includes the repetitive structure of formula (II), and the aluminum of the repetitive structure of formula (II) is bonded with the aluminum of the aluminum-containing material of the thin-film encapsulation layer.

In some embodiments, the thin-film encapsulation layer 13 includes a plurality of encapsulation sub-layers, which, for example, includes an encapsulation organic layer and an encapsulation inorganic layer. In some embodiments, the encapsulation organic layer is disposed on the pixel layer 12 and includes, but is not limited to, acrylic avid resin, epoxy resin, SiOC, or a combination thereof. In some embodiments, the encapsulation inorganic layer is disposed on the encapsulation organic layer and includes, but is not limited to, the aluminum-containing material and/or silicon nitride.

In some embodiments, the cover layer 21 further includes an additive; examples of the additive include, but are not limited to, a hydrophobic monomer, a nano-silicon dioxide, a leveling agent, or a combination thereof. In some embodiments, the hydrophobic monomer can smooth the surface of the cover layer and increase the hardness of the cover layer 21, examples of the hydrophobic monomer include, but are not limited to, 1H,1H,2H,2H-perfluorooctyltriethoxysilane (PFOTES), 2,2,3,3,4,4,4-heptafluoro-1-butanol, or a combination thereof. In some embodiments, the nano-silicon dioxides are distributed evenly across the cover layer 21.

The present invention further provides a method for manufacturing a display device. In some embodiments, the manufacturing method is used to manufacture display devices. The manufacturing method includes various operations, and the following description and discussion shall not be construed as a limitation to the order in which the operations take place.

The manufacturing method comprises, providing a dual-curable sol-gel composition, wherein the dual-curable sol-gel composition comprises a silicon-containing monomer, an aluminum-containing monomer, a solvent, and a polymerization initiator; applying the dual-curable sol-gel composition on a surface of a thin-film encapsulation layer of an organic light-emitting element, wherein the thin-film encapsulation layer includes an aluminum-containing material; and curing the dual-curable sol-gel composition with a UV radiation and a at curing temperature, thereby forming a cover layer on the surface of the thin-film encapsulation layer, wherein the curing temperature is a temperature that does not damage the organic light-emitting device.

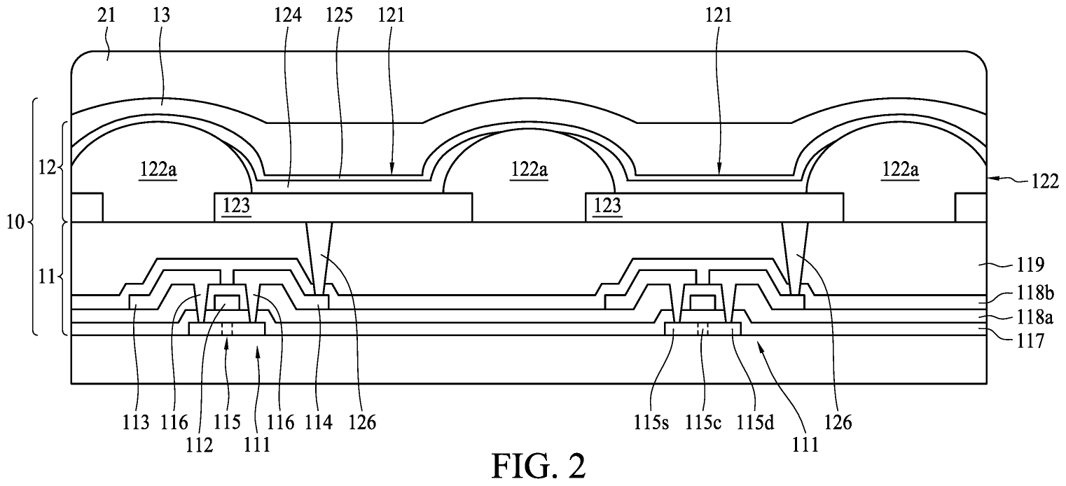

FIGS. 2, 4 and 5 cross-sectional views taken alone of the line A-A′ in FIG. 1, and illustrate the illustrative operations of the method for manufacturing the exemplary display device. In some embodiments, operations illustrated in FIGS. 2, 4 and 5 can be used to provide or manufacture the display device shown in FIG. 1.

As shown in FIG. 2, the organic light-emitting element 10 comprises at least two main layers. The first one is a pixel layer 12, wherein the pixel layer 12 includes a recess array of the array of light-emitting pixels 121 and is configured for emit lights for the organic light-emitting element 10. The light-emitting pixel 121 includes a light-emitting material layer 124. The other one is a circuit layer 11, which is electrically coupled to the pixel layer 12 and stacked vertically with the pixel layer 12. The circuit layer 11 supplies the power and control signal to the pixel layer 12, so as to display colors or patterns as desired. A thin-film encapsulation layer 13 is disposed on the pixel layer 12 of the organic light-emitting element 10, and the dual-curable sol-gel composition 210 is applied on a surface of the thin-film encapsulation layer 13.

In some embodiments, the circuit layer 11 includes a thin-film transistor (TFT) 111 disposed on a substrate 30. In some embodiments, the substrate 30 is flexible, examples of which included, but are not limited to, a polymer substrate or a plastic substrate. In some embodiments, the substrate 30 is rigid, examples of which included, but are not limited to, a glass substrate, a quartz substrate or a silicon-based substrate.

In some embodiments, the TFT 111 includes a gate 112, a source 113, a drain 114, and a semiconductor layer 115. In some embodiments, the semiconductor layer 115 includes a source region 115s electrically connected with the source 113, a drain region 115d electrically connected with the drain 114, and a channel region 115c disposed between the source region 115s and the drain region 115d. In some embodiments, the gate 112 locates above the channel region 115c and overlaps with the channel region 115c. In some embodiments, the source 113 is electrically connected with the source region 115s via a conductive plug 116 formed between a gate insulating layer 117 and an inter-layer insulating layer 118a, and the drain 114 is electrically connected with the drain region 115d via the conductive plug 116 formed between the gate insulating layer 117 and the inter-layer insulating layer 118a.

In some embodiments, the gate insulating layer 117 is formed on the substrate 30 and covers the semiconductor layer 115. The gate insulating layer 117 may have a single-layered or multi-layered structure, and the material thereof may include an inorganic material, an organic material, or any other suitable insulating materials. In some embodiments, the inter-layer insulating layer 118a I formed on the gate insulating layer 117 and covers the gate 112. The inter-layer insulating layer 118a may have a single-layered or multi-layered structure, and the material thereof may include an inorganic material, an organic material, or any other suitable materials.

In some embodiments, an inter-layer insulating layer 118b is formed on the inter-layer insulating layer 118a and covers the TFT 111, so as to provide the functions of insulation and protection. The inter-layer insulating layer 118b may have a single-layered or multi-layered structure, and the material thereof may be the same as or different from the inter-layer insulating layer 118a.

In some embodiments, a planarization layer 119 is formed on the inter-layer insulating layer 118b and covers the TFT 111, so as to provide the functions of protection and planarization. The planarization layer 119 may have a single-layered or multi-layered structure.

In some embodiments, the circuit layer 11 includes at least two TFTs 111 disposed on the substrate 30. In some embodiments, the circuit layer 11 further includes at least one capacitor. In some embodiments, more than one TFTs 111 are disposed to form electrical connection with the capacitor and light-emitting pixels 121.

In some embodiments, the pixel layer 12 includes a pixel defining layer 122. In some embodiments, the pixel defining layer 122 has a plurality of bumps 122a that are spaced from one another, wherein the recess between any two adjacent bumps 122a is defined as the pattern of the light-emitting pixels 121. As could be appreciated by persons having ordinary skill in the art, from the perspective of the cross-sectional view, the bumps 122a are depicted in a disconnected manner; however, from the perspective of the top view in FIG. 1, the bumps 122a may connect with one another via other portions of the pixel defining layer 122.

In some embodiments, the light-emitting pixels 121 has a first electrode 123 disposed above the circuit layer 11. In some embodiments, the first electrode 123 is the anode of the light-emitting pixels 121. The first electrode 123 may be partially covered by the bumps 122a. As shown in FIG. 2, the peripheral area of the first electrode 123 is covered by the bumps 122a. In some embodiments, the sidewall of the first electrode 123 is in contact with the bumps 122a completely. The first electrode 123 includes, but is not limited to, Ag, Al, Mg, Au, ITO, IZO, AlCu alloy, AgMo alloy, or a combination thereof.

In some embodiments, a second electrode 125 is disposed above the light-emitting material layer 124. In some embodiments, the second electrode 125 is the cathode of the light-emitting pixels 121. In some embodiments, the second electrode 125 is patterned in such a way that is only covers the effective light-emitting area of each light-emitting pixels 121. In some embodiments, the second electrode 125 is in contact with the light-emitting material layer 124. As shown in FIG. 2, the second electrode 125 may be continuously disposed above the light-emitting material layer 124 and the bumps 122a. In other words, the second electrode 125 is the common electrode to a plurality of light-emitting pixels 121. In some cases, the second electrode 125 is the common electrode to all light-emitting pixels 121 in the pixel layer 12.

In some embodiments, each light-emitting pixel 121 may emit light with a different wavelength. In some embodiments, the light-emitting material layer 124 of each light-emitting pixel 121 includes different organic light-emitting materials. For example, one light-emitting pixel 121 emits red light, another light-emitting pixel 121 emits blue light, and yet another light-emitting pixel 121 emits green light; however, the present disclosure is not limited thereto.

In some embodiments, the first electrode 123 is electrically connected with the TFT 111 via the conductive plug 126 formed in the planarization layer 119 and inter-layer insulating layers 118a, 118b. It should be noted that the subsequent process operations cannot damage the portions that have been formed previously. For example, the light-emitting material layer 124 of the pixel layer 12 has a poor high-temperature tolerance, and it shall be taken into consideration that all the processes carried out after the formation of the pixel layer 12 cannot damage the pixel layer 12.

In some embodiments, the thin-film encapsulation layer 13 includes an aluminum-containing material. The thin-film encapsulation layer 13 is the same as the one described above, and a detailed description thereof is omitted here for the sake of brevity.

The dual-curable sol-gel composition 210 is applied on a surface of the thin-film encapsulation layer 13. The dual-curable sol-gel composition 210 includes a silicon-containing monomer, an aluminum-containing monomer, a solvent, and a polymerization initiator. The silicon-containing monomer is used for forming the silicon-containing unit and the bridging unit of the cover layer 21, and the aluminum-containing monomer is used for forming the aluminum-containing unit of the cover layer 21. The polymerization initiator can cause the curing of the dual-curable sol-gel composition under the UV radiation and at a curing temperature, thereby forming the cover layer 21.

In some embodiments, the dual-curable sol-gel composition 210 is made by first mixing a dispersion uniformly so that the dispersion becomes the gel state of sol-gel, followed by the addition of the polymerization initiator, thereby obtaining the dual-curable sol-gel composition 210.

For example, the dispersion may be made into the gel state of sol-gel by hydrolysis followed by condensation reaction; however, the present embodiment is not limited thereto. In some embodiments, the dispersion includes aluminum alkoxide, silicon alkoxide, an alcohol solvent, water, and an acid catalyst. Examples of the acid catalyst include, but are not limited to, hydrochloric acid, nitric acid, acetic acid, oxalic acid, sulfuric acid, or a combination thereof. The dispersion may include, for example, 35-60 wt % of silicon alkoxide, 8-25 wt % of aluminum alkoxide, 20-35 wt % of the alcohol solvent, 0.1-10 wt % of water, and a suitable amount of acid catalyst. The dispersion may include, for example, 40-55 wt % of silicon alkoxide, 10-23 wt % of aluminum alkoxide, 20-30 wt % of the alcohol solvent, 0.1-5 wt % of water, and a suitable amount of acid catalyst.

In some embodiments, the dual-curable sol-gel composition 210 is formed by uniformly mixing a silicon sol-gel and an aluminum sol-gel, wherein the silicon sol-gel is formed by uniformly mixing silicon alkoxide, the alcohol solvent, water and the acid catalyst and subjecting the mixture to a polymerization reaction. The silicon sol-gel may include, for example, 30-45 wt % of silicon alkoxide, 5-15 wt % of water, and 45-55 wt % of the alcohol solvent. The aluminum sol-gel is formed by uniformly mixing aluminum alkoxide, the alcohol solvent, water and the acid catalyst and subjecting the mixture to a polymerization reaction. The aluminum sol-gel may include, for example, 35-50 wt % of silicon alkoxide, 30-40 wt % of the alcohol solvent. The aluminum sol-gel may further include a chelating agent, for example, 20-30 wt % of the chelating agent.

In some embodiments, the dual-curable sol-gel composition 210 has a pH of less than 7, or less than 4; for example, the amount of the acid catalyst is used to adjust the pH value. In some embodiments, the polymerization initiator includes a photoinitiator. In some embodiments, the polymerization initiator includes a photoinitiator and a thermal curing agent. The dual-curable sol-gel composition includes, for example, 0.1-0.7 wt % of the photoinitiator and 0-0.5 wt % of the thermal curing agent, or includes, for example, 0.3-0.6 wt % of the photoinitiator and 0-0.35 wt % of the thermal curing agent. In some embodiments, the weight ratio between silicon and aluminum in the dual-curable sol-gel composition 210 is 1:1 to 1:5.

In some embodiments, the dual-curable sol-gel composition 210 includes the dispersion in the gel state of sol-gel, and the dispersion in the gel state of sol-gel includes the structure of the following formula (III),

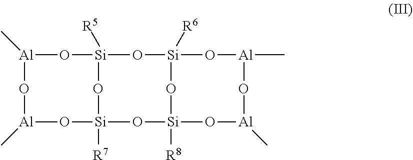

wherein, R⁵, R⁶, R⁷ and R⁸ comprise, independently a (C₃-C₂₀) carbon chain and a reactive functional group bonded with the carbon chain. In some embodiments, R⁵, R⁶, R⁷ and R⁸ comprise, independently, (C₃-C₈) carbon chain and the reactive functional group bonded with the carbon chain. The carbon chain, such as —(CH₂)—, is used to form the bridging unit, but the present embodiments are not limited thereto. In some embodiments, the functional group is a UV-curable group. In some embodiments, R₅, R₆, R₇ and R₈ is independently represented

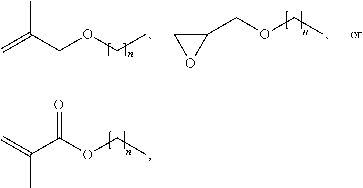

wherein, n is an integer between 3 and 20.

In some embodiments, the dual-curable sol-gel composition 210 includes the dispersion in the gel state of sol-gel, and the dispersion in the gel state of sol-gel includes the structure of the following formula (IV),

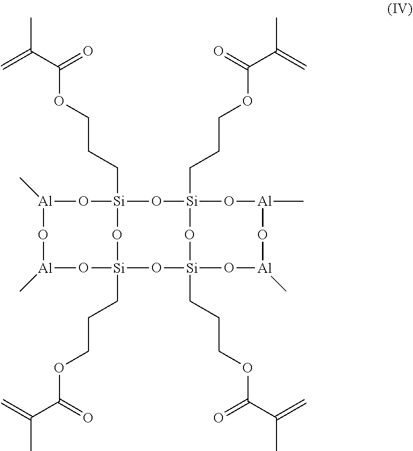

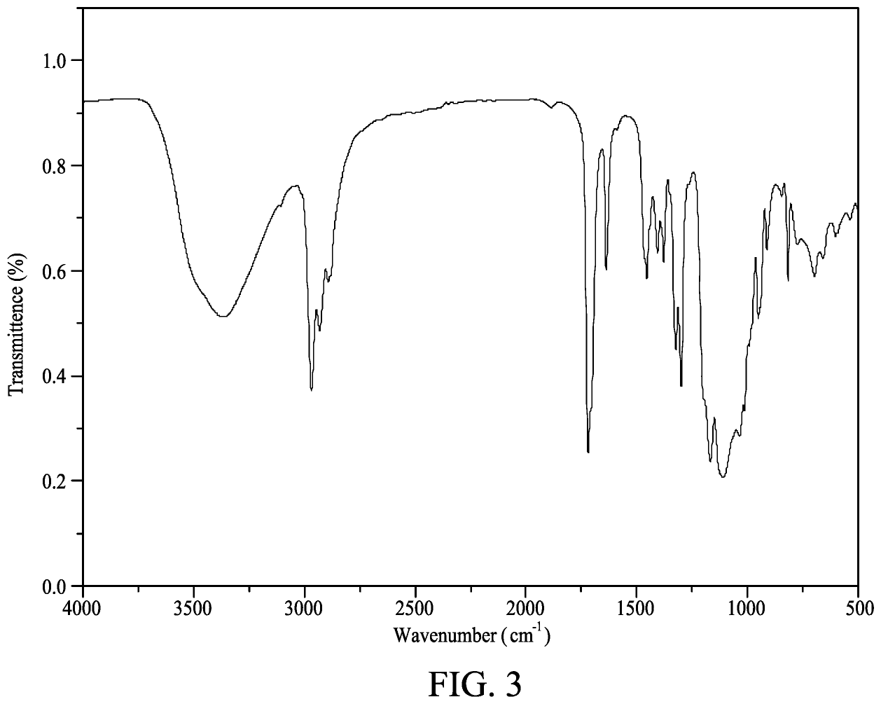

FIG. 3 is an IR spectrum. In some embodiments, the IR spectrum as shown in FIG. 3 confirms that the dispersion in the gel state of sol-gel includes the compound having the structure of formula (IV).

Examples of the aluminum alkoxide include, but are not limited to, aluminum butoxyethoxide, aluminum-tri-sec butoxide, aluminum ethoxide, aluminum methoxide, and a combination thereof.

In some embodiments, the silicon alkoxide includes a (C₃-C₂₀) carbon chain and a reactive functional group. Examples of the reactive functional group include, but are not limited to, vinyl group, epoxy group, styryl group, methacryloxy group, acryloxy group, amino group, ureide group, isocyanate group, isocyanurate group, mercapto group, and a combination thereof.

Examples of the silicon alkoxide include, but are not limited to, trimethoxysilane, vinyltriethoxysilane, 2-(3,4-epoxycyclohexyl)ethyltrimethoxysilane, 3-glycidoxypropyl methyldimethoxysilane, 3-glycidoxypropyl trimethoxysilane, 3-epoxypropoxypropyl methyldiethoxysilane, 3-glycidoxypropyl triethoxysilane, 3-acryloxpropyl trimethoxysilane, N-2-(aminoethyl)-3-aminopropyl, N-2-(aminoethyl)-3-aminopropyltrimethoxy, 3-aminopropyltrimethyl, propyltri ethoxysilane, 3-triethoxysilyl-N-(1,3-dimethyl-butylidene) propylamine, N-phenyl-3-aminopropyltrimethoxy, N-(vinylbenzyl)-2-aminoethyl-3-aminopropyltrimethoxysilane hydrochloride, 3-ureidopropyltrialkoxysilane, 3-isocyanatepropyltriethoxysilane, tris-(trimethoxymethylsilane)isocyanurate, 3-mercaptopropylmethyldimethoxysilane, 3-mercaptopropyltrimethoxysilane, and a combination thereof.

Examples of the alcohol solvent include, but are not limited to, methanol, ethanol, propanol, isopropanol, n-butanol, tert-butanol, methoxypropanol, ethylene glycol and/or diethylene glycol butyl ether. In some embodiments, the alcohol solvent is ethanol.

The dual-curable sol-gel composition 210 may further include an additive, wherein the additive is selected from the group consisting of, a hydrophobic monomer, nano-silicon dioxide, a leveling agent, a hydrophobic sol-gel, or a combination thereof. The types and amounts of the additives may be adjusted as needed, and one or more additives may be used. For example, when the weight of the dispersion in the gel state of sol-gel is 100 wt %, an additional 1-95 wt % of additive(s) may be added. For example, 1-5 wt % of a leveling agent, 5-20 wt % of nano-silicon dioxide, 5-20 wt % of a hydrophobic monomer, and/or 10-60 wt % of hydrophobic sol-gel may be added. For example, 1-3 wt % of a leveling agent, 5-15 wt % of nano-silicon dioxide, 5-20 wt % of a hydrophobic monomer, and/or 30-55 wt % of hydrophobic sol-gel may be added. The diameters of nano-silicon dioxides may be, for example, 50-900 nm or 100-500 nm.

There is no particular limitation with respect to the way of applying the dual-curable sol-gel composition 210 on the thin-film encapsulation layer 13; for example, it can be applied using spin coating or any suitable means; and the present embodiment is not limited thereto. In some embodiments, the surface of the thin-film encapsulation layer 13 is not flat; for example, it may be conformal to the pixel layer 12. In some embodiments, the dual-curable sol-gel composition 210 applied on the thin-film encapsulation layer 13 has a planarized upper surface.

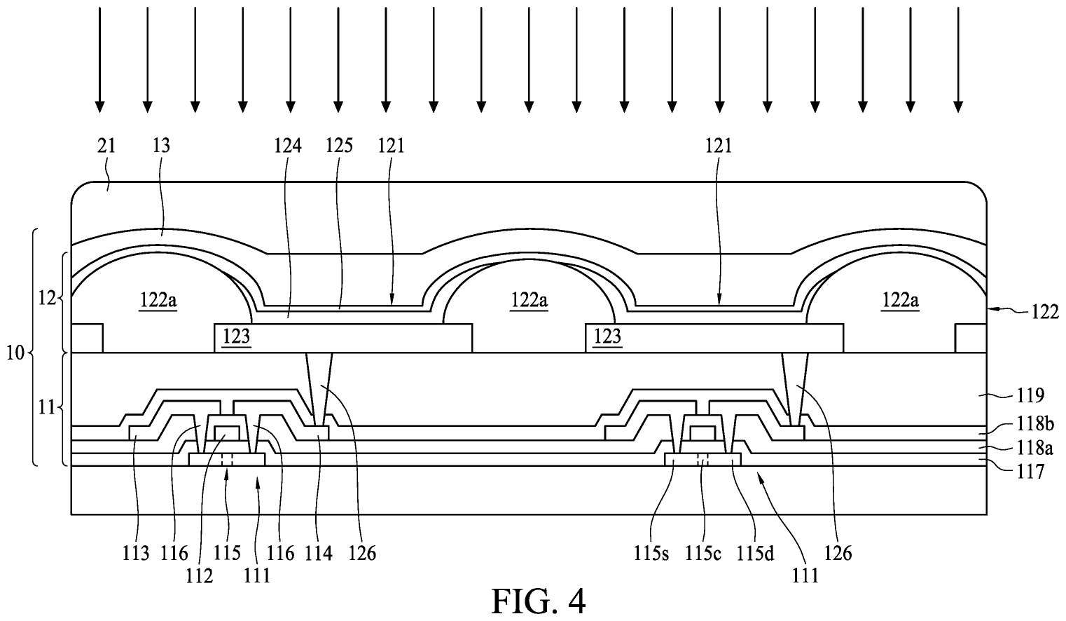

As shown in FIG. 4, the dual-curable sol-gel composition is cured using a UV radiation and under a curing temperature. In some embodiments, the dual-curable sol-gel composition is first subjected to photocuring using the UV radiation, followed by thermal-curing at the curing temperature. When the dual-curable sol-gel composition 210 is irradiated with UV radiation, the reactive functional groups of the silicon-containing monomer are bonded with one another to form the bridging unit; for example, the bonds between R¹ and R² and the bonds between R³ and R⁴ in formula (II) are formed, so that the dual-curable sol-gel composition 210 is sufficiently cross-linked to impart the wearability thereto. In some embodiments, the application of UV radiation is not enough to form the network structure with sufficient hardness, and hence, the dual-curable sol-gel composition 210 is heated to the curing temperature. The curing temperature cannot damage the display device, particularly, the organic light-emitting element 10. In some embodiments, the curing temperature is below 200° C., below 150° C., below 130° C., or between 60-130° C.

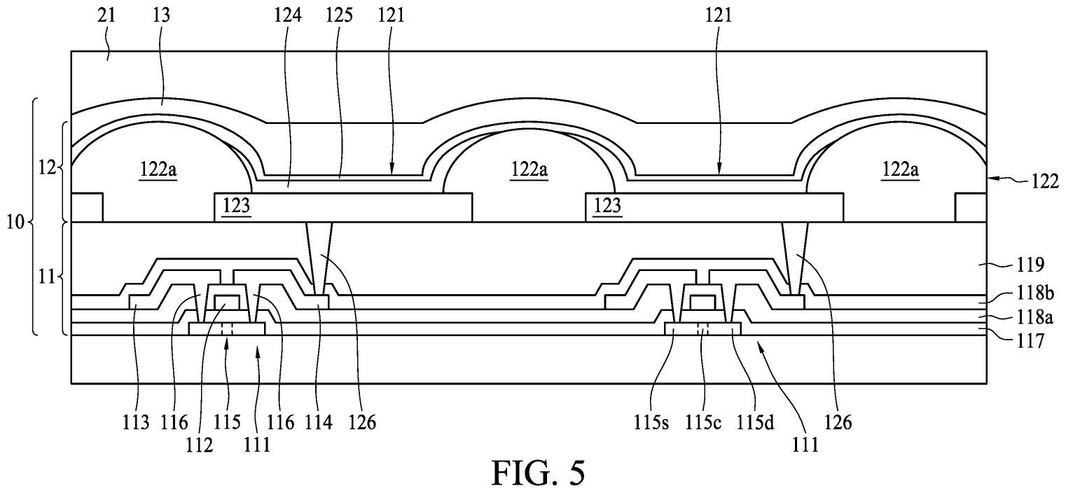

As shown in FIG. 5, after the dual-curable sol-gel composition 210 is cured, a cover layer 21 that is flexible, mechanically integral and wearable is formed. In some embodiments, the cover layer 21 has a planarized upper surface.

### EMBODIMENTS

The following embodiments are provided to further describe the present invention; yet, it should be appreciated that these embodiments are for illustrative purposes, and shall not be construed as limitations to the implementation of the present invention.

### Embodiment 1

44 wt % (relative weight, same as below) of 3-methylacryloxypropyl trimethoxysilane, 0.22 wt % of oxalic acid, 9.53 wt % of deionized water and 46.11 wt % of 2-butanol were fully stirred under room temperature and normal pressure so that the reactants were mixed uniformly and subjected to polymerization reaction, thereby obtaining a silicon sol-gel (hereinafter, 44%-silicon sol-gel).

### Embodiment 2

30.56 wt % (relative weight, same as below) of 3-methylacryloxypropyl trimethoxysilane, 0.30 wt % of oxalic acid, 14.42 wt % of deionized water and 54.7 wt % of 2-butanol were fully stirred under room temperature and normal pressure so that the reactants were mixed uniformly and subjected to polymerization reaction, thereby obtaining a silicon sol-gel (hereinafter, 30%-silicon sol-gel).

### Embodiment 3

First, 41.8 wt % of sec-butanol aluminum [Al(OC₄H9), abbreviated as ASB below] and 35.0 wt % of 2-butanol were mixed uniformly at 85 to 90° C. Then, 22.05 wt % of ethyl acetoacetate (EAcAc) was added as the chelating agent for ASB, and 1.13 wt % of nitric acid was added as the catalyst, the reactants were refluxed for 7-8 hours for polymerization reaction, thereafter, the mixture was cooled and filtered with a 0.22 μm filter, thereby obtaining an aluminum sol-gel.

### Embodiment 4

4.75 g of the 44%-silicon sol-gel of Embodiment 1 and 0.25 g of the aluminum sol-gel of Embodiment 3 were fully stirred so that the reactants were mixed uniformly and subjected to polymerization reaction, thereby forming a dispersion in the gel state of sol-gel. Then, 0.0164 g of Darocur 1173 (purchased from Sigma-Aldrich) and 0.066 g of IRGACURE 819 (purchased from BASF) were added as the photoinitiators, and 0.025 g of tetrabutylammonium acetate was added as the thermal curing agent. Next, 1 g of 2-butanol was added, and the reactants were mixed uniformly, thereby obtaining a dual-curable sol-gel composition with the pH of 1.69.

The dual-curable sol-gel composition was coated on a rigid glass substrate and a flexible colorless polyimine (CPI) substrate (purchased from Taimide Tech Inc.; Cat. No. OT-050; thickness: 50 μm), wherein the thickness of the coating layer was less than 10 μm. The dual-curable sol-gel composition was first cured with UV radiation having a primary wavelength of 365 nm (intensity: 20 mw/cm²) and a secondary wavelength of 254 nm (intensity: 10 mw/cm²) for 300 seconds, so that the dual-curable sol-gel composition formed a cover layer on the glass substrate and the CPI substrate, respectively. The pH value and curing methods of the dual-curable sol-gel composition are summarized in Table 1.

The cover layers were subjected respectively, to the pencil hardness test, and the cover layer formed on the CPI substrate was subjected to the bending test. For conducting the bending test, the CPI substrate and the cover layer formed thereon was placed flatly on the testing platform of the flexible endurance tester (purchased from Japan YUASA; Cat. No. DLDM 111LHB); the cover layer was then bended inwardly to radius of 2 mm for 300,000 times, and the cover layer was observed for cracks. The results of each test are summarized in Table 1, wherein for the bending test, ◯ represents no cracks, and X represents cracks.

### Embodiment 5

Methods for testing the composition of the dual-curable sol-gel composition were the same as those described in Embodiment 4. The present embodiment differs from Embodiment 4 in that the dual-curable sol-gel composition was only subjected to thermal curing at 130° C. for 2 hours without applying the UV radiation.

The curing methods of the dual-curable sol-gel composition and results of each test are summarized in Table 1.

### Embodiments 6-7

Compositions of the dual-curable sol-gel compositions according to Embodiments 6-7 are similar to that of Embodiment 4 except that the in Embodiments 6-7, the compositions were first irradiated with UV radiation for photocuring, followed by thermal curing at the curing temperature. Further, in Embodiment 7, the addition amount of the acid catalyst (e.g., hydrochloric acid, nitric acid, acetic acid, oxalic acid, sulfuric acid, etc.) was adjusted so that the pH value of the dual-curable sol-gel composition was different from that of Embodiment 4.

The curing methods of the dual-curable sol-gel compositions and results of each test are summarized in Table 1.

TABLE 1

| | | Curing method | | pencil hardness | | |
|---|---|---|---|---|---|---|
| | | | Curing temp. | test | | bending |
| Embodi- | | UV | and curing | rigid | | test |
| ment | pH | curing | time | glass | CPI | CPI |
| 4 | 1.69 | yes | none | <3H | Not | Not |
| | | | | | tested | tested |
| 5 | 1.69 | none | 130° C./2 hrs | 8H | <3H | X |
| 6 | 1.69 | none | 130° C./2 hrs | 9H | 3H | ◯ |
| 7 | about 2 | Yes | 80° C./2 hrs | 7H | <3H | ◯ |

As can be seen from Table 1, after the photocuring with the UV radiation, a cover layer with good hardness and bending endurance could be achieved by thermal curing at a curing temperature smaller than or equal to 130° C.

### Embodiment 8

52.74 wt % (relative weight, same as below) of 3-methylacryloxypropyl trimethoxysilane, 10.46 wt % of ASB, a suitable amount of acid catalyst, 0.76 wt % of deionized water and 25.52 wt % of ethanol were fully stirred under room temperature and normal pressure so that the reactants were mixed uniformly and subjected to polymerization reaction, thereby obtaining a dispersion in the gel state of sol-gel. Then, 0.26 wt % of Darocur 1173 and 0.126 wt % of IRGACURE were added as the photoinitiators, and 0.32 wt % of tetrabutylammonium acetate was added as the thermal curing agent. The reactants were mixed uniformly, thereby obtaining a dual-curable sol-gel composition with the pH of 2.58.

The dual-curable sol-gel composition was coated on a rigid glass substrate and a flexible colorless polyimine (CPI) substrate (purchased from Taimide Tech Inc.; Cat. No. OT-050; thickness=50 μm), wherein the thickness of the coating layer was less than 10 μm. The dual-curable sol-gel composition was first cured with UV radiation having a primary wavelength of 365 nm (intensity: 20 mw/cm²) and a secondary wavelength of 254 nm (intensity: 10 mw/cm²) for 300 seconds, followed by thermal curing at a curing temperature of 130° C. for 2 hours, so that the dual-curable sol-gel composition formed a cover layer on the glass substrate and the CPI substrate, respectively. The composition and pH value of the dual-curable sol-gel composition are summarized in Table 2.

The cover layers were subjected respectively, to the pencil hardness test, and the cover layer formed on the CPI substrate was subjected to the bending test; the testing methods were the same as those described in Embodiment 4. The cover layer formed on the CPI substrate was further subjected to the light transmittance test (under 550 nm); the results of each test are summarized in Table 2.

### Embodiments 9-16

Compositions of the dual-curable sol-gel compositions in Embodiments 9-16 were similar to that of Embodiment 8 except the addition amount of each component. The compositions and pH values of these dual-curable sol-gel compositions are detailed in Table 2.

It should be noted that, the dual-curable sol-gel composition of Embodiment 11 further comprised 53.6 wt % of hydrophobic sol-gel, based on 100 wt % of the 11 dispersion in the gel state of sol-gel of Embodiment 11. The hydrophobic sol-gel comprised PFOTES, hydrochloric acid and ethanol.

The dual-curable sol-gel composition of Embodiment 12 further comprised 10 wt % of nano-silicon dioxide particles (particle size: 20 nm, dispersed across IPA), based on 100 wt % of the dispersion in the gel state of sol-gel of Embodiment 12.

The dual-curable sol-gel composition of Embodiment 13 further comprised 53.6 wt % of aforementioned hydrophobic sol-gel and 10 wt % of aforementioned nano-silicon dioxide particles, based on 100 wt % of the dispersion in the gel state of sol-gel of Embodiment 13.

The dual-curable sol-gel composition of Embodiment 14 further comprised 6.8 wt % of 2,2,3,3,4,4,4-heptafluoro-1-butanol as the hydrophobic monomer, based on 100 wt % of the dispersion in the gel state of sol-gel of Embodiment 14. The dual-curable sol-gel composition of Embodiment 15 further comprised 17.94 wt % of 2,2,3,3,4,4,4-heptafluoro-1-butanol as the hydrophobic monomer.

The dual-curable sol-gel composition of Embodiment 16 further comprised 17.94 wt % of 2,2,3,3,4,4,4-heptafluoro-1-butanol as the hydrophobic monomer, 10 wt % of aforementioned nano-silicon dioxide particles, and 1 wt % of BYK3760 as the leveling agent, based on 100 wt % of the dispersion in the gel state of sol-gel of Embodiment 16.

TABLE 2

| | | Embodiment | | | | | | | | |
|---|---|---|---|---|---|---|---|---|---|---|
| Event | | 8 | 9 | 10 | 11 | 12 | 13 | 14 | 15 | 16 |
| 3-methylacryloxypropyl | | 53.45 | 48.32 | 43.91 | 48.32 | 48.32 | 48.32 | 42.81 | 37.85 | 37.85 |
| trimethoxysilane (wt %) | | | | | | | | | | |
| ASB(wt %) | | 10.46 | 19.19 | 21.48 | 19.19 | 19.19 | 19.19 | 16.75 | 14.73 | 14.73 |
| deionized water (wt %) | | 0.76 | 0.69 | 0.62 | 0.69 | 0.69 | 0.69 | 0.61 | 0.54 | 0.54 |
| ethanol (wt %) | | 25.52 | 23.11 | 25.88 | 23.11 | 23.11 | 23.11 | 25.2 | 22.16 | 22.16 |
| solution of acid | | 9.81 | 8.69 | 8.11 | 8.69 | 8.69 | 8.69 | 7.83 | 6.78 | 6.78 |
| catalyst (wt %) | | | | | | | | | | |
| pH | | 2.58 | 2.60 | 2.60 | 2.60 | 2.60 | 2.97 | 3.65 | 1.74 | 2.78 |
| Darocur 1173(wt %) | | 0.26 | 0.43 | 0.18 | 0.43 | 0.43 | 0.43 | 0.23 | 0.26 | 0.26 |
| IRGACURE 819(wt %) | | 0.126 | 0.100 | 0.107 | 0.100 | 0.100 | 0.100 | 0.100 | 0.126 | 0.126 |
| tetrabutylammonium | | 0.32 | 0.29 | 0.26 | 0.29 | 0.29 | 0.29 | 0.26 | 0.31 | 0.31 |
| acetate (wt %) | | | | | | | | | | |
| hydrophobic monomer | | 0 | 0 | 0 | 0 | 0 | 0 | 6.8 | 17.94 | 17.94 |
| (wt %) | | | | | | | | | | |
| hydrophobic sol-gel | | 0 | 0 | 0 | 53.6 | 0 | 53.6 | 0 | 0 | 0 |
| (wt %) | | | | | | | | | | |
| nano-silicon dioxide | | 0 | 0 | 0 | 0 | 10 | 10 | 0 | 0 | 10 |
| particles (wt %) | | | | | | | | | | |
| BYK3760(wt %) | | 0 | 0 | 0 | 0 | 0 | 0 | 0 | 0 | 1 |
| pencil | CPI | 3H | 4H | <3H | 4H | 4H | 3H | 3H | 4H | 4H |
| hardness | rigid | 7H | 8H | <7H | 8H | 8H | 7H | 7H | 8H | 9H |
| test | glass | | | | | | | | | |

| | | | | | | | | | |
|---|---|---|---|---|---|---|---|---|---|
| bending test | ◯ | ◯ | ◯ | ◯ | ◯ | ◯ | ◯ | ◯ | ◯ |
| Transmittance (%) | 99.8 | 96.1 | 92.3 | 98.6 | 99.8 | 99.8 | 99.8 | 98.1 | 94.3 |

### Embodiment 17

Process steps for the present embodiment are as follows. 48.60 wt % (relative weight, same as below) of 3-methylacryloxypropyl trimethoxysilane, 8.15 wt % of tetraethoxysilane, 9.64 wt % of ASB, a suitable amount of acid catalyst, 0.71 wt % of deionized water and 23.52 wt % of ethanol were fully stirred under room temperature and normal pressure so that the reactants were mixed uniformly and subjected to polymerization reaction, thereby obtaining a dispersion in the gel state of sol-gel. Then, 0.52 wt % of Darocur 1173 and 0.1 wt % of IRGACURE 819 were added as photoinitiators, and the reactants were mixed uniformly to obtain a dual-curable sol-gel composition with a pH of about 2.

The dual-curable sol-gel composition was coated on a rigid glass substrate and a flexible colorless polyimine substrate, and the dual-curable sol-gel composition was cured in accordance with the curing method set forth in Embodiment 8, thereby forming a cover layer on the glass substrate and the CPI substrate, respectively. The composition and pH value of the dual-curable sol-gel composition are summarized in Table 3.

The cover layers were subjected respectively, to the pencil hardness test, and the cover layer formed on the CPI substrate was subjected to the bending test and the light transmittance test; the testing methods were the same as those described in Embodiment 8, and the results of each test are summarized in Table 3.

### Embodiment 18-22

Compositions of the dual-curable sol-gel compositions in Embodiments 18-22 were similar to that of Embodiment 17 except the addition amount of each component. The compositions and pH values of these dual-curable sol-gel compositions are detailed in Table 2.

It should be noted that, the dual-curable sol-gel composition of Embodiments 19-22 further comprised ethyl acetoacetate (EAcAc) as the chelating agent for ASB. The dispersion in the gel state of sol-gel in Embodiments 21-22 further comprised tetrabutylammonium acetate as the thermal curing agent. Furthermore, the dual-curable sol-gel composition of Embodiment 19 further comprised 10 wt % of aforementioned nano-silicon dioxide particles, based on 100 wt % of the dispersion in the gel state of sol-gel of Embodiment 19.

The dual-curable sol-gel composition of Embodiment 20 further comprised 52.8 wt % of aforementioned hydrophobic sol-gel and 12 wt % of aforementioned nano-silicon dioxide particles, based on 100 wt % of the dispersion in the gel state of sol-gel of Embodiment 20.

The dual-curable sol-gel composition of Embodiment 21 further comprised 12.91 wt % of 2,2,3,3,4,4,4-heptafluoro-1-butanol as the hydrophobic monomer, based on 100 wt % of the dispersion in the gel state of sol-gel of Embodiment 21.

The dual-curable sol-gel composition of Embodiment 22 further comprised 16.69 wt % of 2,2,3,3,4,4,4-heptafluoro-1-butanol as the hydrophobic monomer, 10 wt % of aforementioned nano-silicon dioxide particles, and 1 wt % of BYK3760 as the leveling agent, based on 100 wt % of the dispersion in the gel state of sol-gel of Embodiment 22.

TABLE 3

| | | Embodiment | | | | | |
|---|---|---|---|---|---|---|---|
| Event | | 17 | 18 | 19 | 20 | 21 | 22 |
| 3-methylacryloxypropyl | | 48.82 | 44.52 | 37.23 | 43.04 | 32.07 | 32.07 |
| trimethoxysilane (wt %) | | | | | | | |
| tetraethoxysilane (wt %) | | 8.19 | 7.31 | 9.99 | 11.56 | 8.61 | 8.61 |
| EAcAc(wt %) | | 0 | 0 | 6.24 | 7.21 | 5.38 | 5.38 |
| ASB(wt %) | | 9.73 | 17.76 | 12.92 | 14.94 | 11.13 | 11.13 |
| deionized water (wt %) | | 0.71 | 0.69 | 6.48 | 7.49 | 5.58 | 5.58 |
| ethanol (wt %) | | 23.75 | 21.43 | 27.02 | 15.62 | 23.93 | 24.07 |
| solution of acid | | 8.8 | 8.29 | 0.12 | 0.14 | 0.39 | 0.43 |
| catalyst (wt %) | | | | | | | |
| pH | | 2 | 2.2 | 2.13 | 3.13 | 1.65 | 1.78 |
| Darocur 1173(wt %) | | 0.52 | 0.2 | 0.34 | 0.42 | 0.36 | 0.44 |
| IRGACURE 819(wt %) | | 0.1 | 0.1 | 0.102 | 0.11 | 0.1 | 0.1 |
| tetrabutylammonium | | 0 | 0 | 0 | 0 | 0.29 | 0.26 |
| acetate (wt %) | | | | | | | |
| hydrophobic monomer | | 0 | 0 | 0 | 0 | 12.91 | 12.73 |
| (wt %) | | | | | | | |
| hydrophobic sol-gel | | 0 | 0 | 0 | 52.8 | 0 | 0 |
| (wt %) | | | | | | | |
| nano-silicon dioxide | | 0 | 0 | 10 | 12 | 0 | 10 |
| particles (wt %) | | | | | | | |
| BYK3760(wt %) | | 0 | 0 | 0 | 0 | 0 | 1 |
| pencil | 3H | 3H | 4H | 3H | 3H | 3H | 3H |
| hardness | 8H | 8H | 9H | 8H | 9H | 9H | 9H |
| test | | | | | | | |

| | | | | | | |
|---|---|---|---|---|---|---|
| bending test | ◯ | not | X | ◯ | ◯ | ◯ |
| | | tested | | | | |
| Transmittance (%) | 99.8 | 98.9 | 99.8 | 99.5 | 98 | 99.5 |

According to some embodiments of the present disclosure, a display device is disposed with a cover layer. The cover layer may form integrally on the thin-film encapsulation layer of the display device directly, without damaging the display device (for example, organic light-emitting element) and does not require an additional adhesive layer, thereby reducing the manufacturing cost and minimizing the thickness of the display panel. The cover layer may be a flexible hard coating that connects with the thin-film encapsulation layer tightly and has a good hardness, flexibility, wearability and light transmittance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method for manufacturing a display device, the manufacturing method comprising,
providing a dual-curable sol-gel composition, wherein the dual-curable sol-gel composition comprises a silicon-containing monomer, an aluminum-containing monomer, a solvent, and a polymerization initiator;
applying the dual-curable sol-gel composition on a surface of a thin-film encapsulation layer of an organic light-emitting element, wherein the thin-film encapsulation layer comprises an aluminum-containing material; and
curing the dual-curable sol-gel composition with a UV radiation and at a curing temperature, thereby forming a cover layer on the surface of the thin-film encapsulation layer, wherein the curing temperature is a temperature that does not damage the organic light-emitting element.

2. The manufacturing method of claim 1, wherein the dual-curable sol-gel composition is first subject to photo-curing with the UV radiation, and followed by thermal-curing at the curing temperature.

3. The manufacturing method of claim 1, wherein the cover layer comprising a network structure, wherein the network structure includes silicon, aluminum, and oxygen.

4. The manufacturing method of claim 1, wherein the polymerization initiator comprises a photoinitiator and a thermal curing agent.

5. The manufacturing method of claim 1, wherein the curing temperature is below 150° C.

6. The manufacturing method of claim 1, wherein in the dual-curable sol-gel composition, the weight ratio between silicon and aluminum is 1:1 to 1:5.

7. The manufacturing method of claim 1, wherein the cover layer has a light transmittance of no less than 85%.

8. The manufacturing method of claim 1, wherein the dual-curable sol-gel composition has a pH of less than 7.

9. The manufacturing method of claim 1, wherein the dual-curable sol-gel composition further comprises an additive, wherein the additive is selected from the group consisting of a hydrophobic monomer, a nano-silicon dioxide, and a combination thereof.

10. The manufacturing method of claim 1, wherein the dual-curable sol-gel composition comprises an aluminum alkoxide, a silicon alkoxide, an alcohol solvent, a photoinitiator, and a thermal curing agent.

11. The manufacturing method of claim 10, wherein the aluminum alkoxide is selected from the group consisting of aluminum butoxyethoxide, aluminum-tri-sec butoxide, aluminum ethoxide, aluminum methoxide, and a combination thereof.

12. The manufacturing method of claim 10, wherein the silicon alkoxide comprises a (C₃-C₂₀) carbon chain and a reactive functional group, wherein the reactive functional group is selected from the group consisting of vinyl group, epoxy group, styryl group, methacryloxy group, acryloxy group, amino group, ureide group, isocyanate group, isocyanurate group, mercapto group, and a combination thereof.

13. The manufacturing method of claim 10, wherein the silicon alkoxide is selected from the group consisting of, trimethoxysilane, vinyltriethoxysilane, 2-(3,4-epoxycyclohexyl)ethyltrimethoxysilane, 3-glycidoxypropyl methyldimethoxysilane, 3-glycidoxypropyl trimethoxysilane, 3-epoxypropoxypropyl methyldiethoxysilane, 3-glycidoxypropyl triethoxysilane, 3-acryloxpropyl trimethoxysilane, N-2-(aminoethyl)-3-aminopropyl, N-2-(aminoethyl)-3-aminopropyltrimethoxy, 3-aminopropyltrimethyl, propyltriethoxysilane, 3-triethoxysilyl-N-(1,3-dimethyl-butylidene) propylamine, N-phenyl-3-aminopropyltrimethoxy, N-(vinylbenzyl)-2-aminoethyl-3-aminopropyltrimethoxysilane hydrochloride, 3-ureidopropyltrialkoxysilane, 3-isocyanatepropyltriethoxysilane, tris-(trimethoxymethylsilane)isocyanurate, 3-mercaptopropylmethyldimethoxysilane, 3-mercaptopropyltrimethoxysilane, and a combination thereof.

14. A display device, comprising,
an organic light-emitting element, comprising,
a circuit layer,
a pixel layer, formed on the circuit layer; and
a thin-film encapsulation layer, disposed on the pixel layer,
wherein the thin-film encapsulation layer comprises an aluminum-containing material; and
a cover layer, disposed on the thin-film encapsulation layer of the organic light-emitting element, wherein the cover layer comprises a silicon-containing unit, an aluminum-containing unit, and a bridging unit connecting the silicon-containing unit and the aluminum-containing unit;
wherein, the aluminum-containing unit of the cover layer is covalently bonded to the thin-film encapsulation layer.

15. The display device of claim 14, wherein the aluminum-containing unit of the cover layer is covalently bonded to aluminum of the aluminum-containing material in the thin-film encapsulation layer.

16. The display device of claim 14, wherein the cover layer comprises a repeating structure of the following formula (I):
—X—Y—X—B— (I)
wherein, X represents the silicon-containing unit, Y represents the aluminum-containing unit, and B represents the bridging unit.

17. The display device of claim 14, wherein the cover layer comprises the following formula (II): 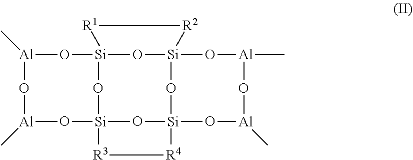
wherein each of R¹, R², R³ and R⁴ is independently 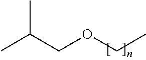
and n is an integer of 3-20.

18. The display device of claim 14, wherein in the cover layer, the weight ratio between silicon and aluminum is 1:1 to 1:5.

19. The display device of claim 14, wherein the cover layer is flexible.

20. The display device of claim 14, wherein the cover layer has a light transmittance of no less than 85%.
